(19) United States
(12) Patent Application Publication
(10) Pub. No.: US 2010/0093184 A1
(43) Pub. Date: Apr. 15, 2010

(54) Method for making a metal oxide layer

(75) Inventors: Tai-Bor Wu, Hsinchu (TW); Cheng-Hao Hou, Hsinchu City (TW)

Correspondence Address: DAVIDSON BERQUIST JACKSON & GOWDEY LLP, 4300 WILSON BLVD., 7TH FLOOR, ARLINGTON, VA, 22203, US

(73) Assignee: NATIONAL TSING HUA UNIVERSITY, Hsinchu (TW)

(21) Appl. No.: 12/588,367

(22) Filed: Oct. 14, 2009

(30) Foreign Application Priority Data
Oct. 15, 2008 (TW) 097139516

(51) Int. Cl. H01L 21/316

(52) U.S. Cl. 438/765; 257/E21.274

(57) ABSTRACT

A method for making a metal oxide layer includes: (a) exposing a substrate having oxygen-containing reaction sites to an environment of a first precursor of an organometallic compound, which contains a metal atom and ligand groups, so as to form a chemisorption layer of the first precursor on the substrate; (b) exposing the chemisorption layer on the substrate to a non-free radical environment of a second precursor after step (a) so as to remove the ligand groups of the chemisorption layer that are unreacted in step (a) and so as to convert the chemisorption layer into a metal oxide layer; and (c) after step (b), exposing the metal oxide layer on the substrate to a free radical-containing gas containing free radicals so as to remove the ligand groups of the chemisorption layer that are left unreacted in step (b).

### CROSS-REFERENCE TO RELATED APPLICATION

This application claims priority of Taiwanese application No. 097139516, filed on Oct. 15, 2008.

### BACKGROUND OF THE INVENTION

1. Field of the Invention

This invention relates to a method for making a metal oxide layer, more particularly to a method involving subjecting free radicals to reaction with unreacted ligand groups of a chemisorption layer of a precursor on a substrate.

2. Description of the Related Art

As IC device dimensions continue to scale down, current leakage can get worse for devices using low dielectric constant (k) material, such as SiO₂, as a material for a gate dielectric layer. Hence, attention has been focused on the use of a high-k dielectric material, such as HfO₂ or Al₂O₃, to replace SiO₂ as the gate dielectric layer.

It has been proposed in the art to use Atomic layer deposition (ALD) techniques to form a high-k gate dielectric layer on a Si substrate for forming a semiconductor device, such as a MOSFET device. In the ALD techniques, a reactant of an organometallic compound, which contains a metal atom and ligands (each of the ligands having an atom chelated to the metal atom), is chemisorbed onto the Si substrate to form a chemisorption layer on the substrate, and water vapor is subsequently brought to react with the chelated atoms of the ligands of the chemisorption layer, which is chelated to the metal atom, so as to remove the ligands from the metal atom of the organometallic compound of the chemisorption layer, thereby forming a discontinuous metal oxide layer (e.g., an island-like metal oxide layer) on the Si substrate. The above steps are then repeated for a number of cycles so as to form a continuous metal oxide layer and to thicken the metal oxide layer to an extent sufficient to serve as the high-k gate dielectric layer. However, during reaction of the water vapor with the ligands of the chemisorption layer, some of the ligands of the chemisorption layer are trapped therein and are left unreacted attributed to the steric hindrance effect of the large molecules of the ligands of the chemisorption layer on the substrate to the water vapor molecules. The steric hindrance effect hinders water vapor molecules from reaching the chelated atoms of the unreacted ligands of the chemisorption layer for reacting therewith. The unreacted ligands (also referred to herein as ligand residuals) that are trapped in the metal oxide layer can cause generation of an interfacial layer during a subsequent gate first process of the MOSFET device, thereby resulting in an increase in equivalent oxide thickness (EOT) of the MOSFET device and an adverse effect on the performance of the MOSFET device.

Hence, there is a need in the art to provide a method chemisorption layer during the ALD process.

### SUMMARY OF THE INVENTION

Therefore, the object of the present invention is to provide a method for making a metal oxide layer that can reduce the amount of ligand residuals in the chemisorption layer.

According to this invention, there is provided a method for making a metal oxide layer that comprises: (a) exposing a substrate having oxygen-containing reaction sites to an environment of a first precursor of an organometallic compound, which contains a metal atom and ligand groups, so as to form a chemisorption layer of the first precursor on the substrate; (b) exposing the chemisorption layer on the substrate to a non-free radical environment of a second precursor after step (a) so as to remove the ligand groups of the chemisorption layer that are left unreacted in step (a) and so as to convert the chemisorption layer into a metal oxide layer; and (c) after step (b), exposing the metal oxide layer on the substrate to a free radical-containing gas containing free radicals so as to remove the ligand groups that are left unreacted and trapped in the metal oxide layer in step (b).

### BRIEF DESCRIPTION OF THE DRAWINGS

Other features and advantages of the present invention will become apparent in the following detailed description of the preferred embodiment of this invention, with reference to the accompanying drawings, in which:

FIG. 1 is a schematic diagram to illustrate the configuration of a system used in the preferred embodiment of a method for making a metal oxide layer according to this invention;

FIG. 2 is a fragmentary partly sectional view of a pipe of the system of FIG. 1 to illustrate that cations and anions of a free radical-containing gas are neutralized by a metal mesh disposed in the pipe;

FIG. 3 is a plot to illustrate the relations between equivalent oxide thickness (EOT) and post deposition annealing (PDA) temperature for Example 1 and Comparative Example 1; and

FIG. 4 is a plot to illustrate the relations between current leakage (J_{g}) and the PDA temperature for Example 1 and Comparative Example 1.

### DETAILED DESCRIPTION OF THE PREFERRED EMBODIMENTS

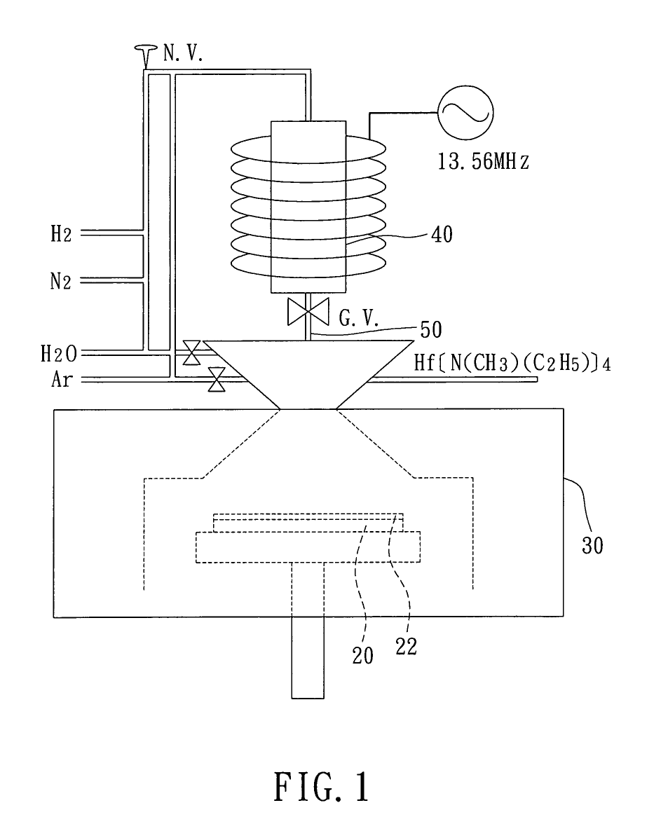

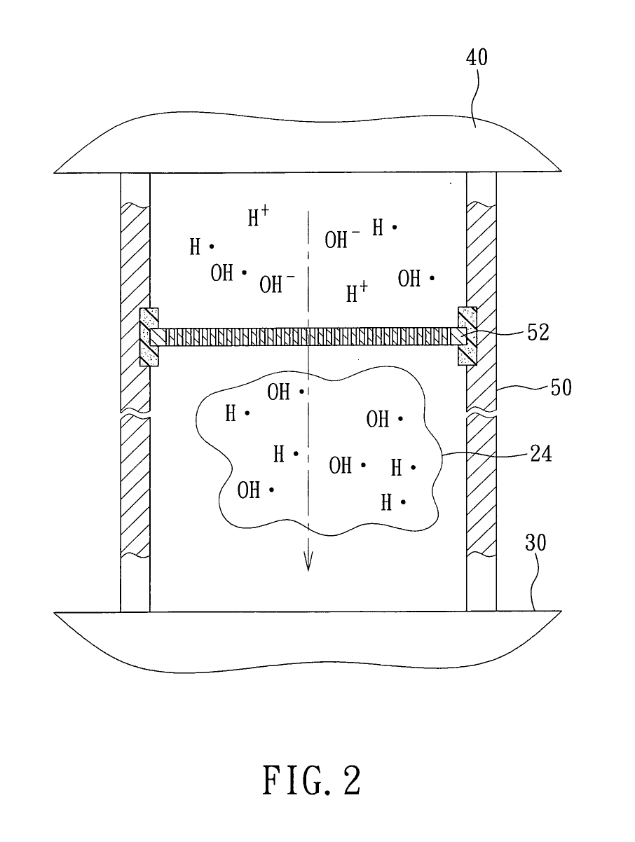

FIGS. 1 and 2 illustrate a system used in the preferred embodiment of a method for making a metal oxide layer 22 according to the present invention. The system includes a deposition reactor 30 and a plasma generator 40.

The method includes: (a) exposing a substrate 20, such as a Si substrate, having oxygen-containing reaction sites to an environment of a first precursor of an organometallic compound, which contains a metal atom and ligand groups chelated to the metal atom, in the deposition reactor 30 so as to form a chemisorption layer of the first precursor on the substrate 20; (b) exposing the chemisorption layer on the substrate 20 to a non-free radical environment of a second precursor after step (a) so as to remove the ligand groups of the chemisorption layer that are left unreacted in step (a) and so as to convert the chemisorption layer into the metal oxide layer 22, wherein when the second precursor is e.g., water vapor, new oxygen-containing reaction sites are formed on the metal oxide layer 22 through reaction of the water vapor with the ligand groups; (c) after step (b), exposing the metal oxide layer 22 on the substrate 20 to a free radical-containing gas 24 containing free radicals for a period of time in the deposition reactor 30 so as to remove the ligand groups of the chemisorption layer that are left unreacted and trapped in the metal oxide layer 22 in step (b), wherein when the free radicals include oxygen-containing free radicals, the latter can form new oxygen-containing reaction sites on the metal oxide layer 22 by bonding to the metal oxide layer 22 through chemisorption mechanism; (d) exposing the metal oxide layer 22 on the substrate 20 to the environment of the first precursor for forming a chemisorption layer of the first precursor on the metal oxide layer 22 on the substrate 20; (e) after step (d), exposing the chemisorption layer on the metal oxide layer 22 on the substrate 20 to the environment of the second precursor for removing the ligand groups of the chemisorption layer that are left unreacted in step (d) so as to thicken the metal oxide layer 22; (f) after step (e), exposing the thickened metal oxide layer 22 on the substrate 20 to the free radical-containing gas 24 for a period of time for removing the ligand groups that are left unreacted and trapped in the thickened metal oxide layer 22 in step (e); and (g) repeating steps (d)-(f) until a predetermined layer thickness of the metal oxide layer 22 is achieved. The number of the repeated cycles of steps (d)-(f) depends on the desired layer thickness of the metal oxide layer 22 to be achieved.

The free radical-containing gas 24 is formed by using the plasma generator 40 having a first working pressure, and is subsequently introduced into the deposition reactor 30 from the plasma generator 40 through a gate valve. The deposition reactor 30 has a second working pressure. The first working pressure is greater than the second working pressure so as to permit discharging of the free radical-containing gas 24 from the plasma generator 40 into the deposition reactor 30.

Preferably, the plasma generator 40 is connected to the deposition reactor 30 through a connecting pipe 50. The method further includes passing the free radical-containing gas 24 through a metal mesh 52 disposed in the connecting pipe 50 during discharging of the free radical-containing gas 24 from the plasma generator 40 into the deposition reactor 30 so as to permit cations and anions contained in the free radical-containing gas to be neutralized by the metal mesh 52, thereby eliminating damage to the metal oxide layer 22 due to bombardment of the cations and anions onto the metal oxide layer 22.

Preferably, the free radicals are formed by ionizing a free radical source in the plasma generator 40. More preferably, the free radical source is H₂O, O₂, H₂O₂, O₃, N₂O, or combinations thereof. The free radical-containing gas 24 further includes an inert gas serving as a carrying gas so as to introduce the free radicals from the plasma generator 40 into the deposition reactor 30. In an example of the present invention, the second precursor is H₂O, and the inert gas and the free radical source are Ar and H₂O, respectively. As such, the free radical-containing gas 24 thus formed in the example contains the free radicals of OH. and H..

Preferably, the organometallic compound is a metal amide derivative, and has a formula of A (NR¹R²)ₙ, in which A is a metal atom selected from Hf, Ti, Al, Zr, Ta, Y, and La, R¹ and R² can be the same or different and are independently C₁˜C₂ alkyl, C₂˜C₃ alkenyl, or H, and 3≦n≦5. More preferably, A is Hf, and R¹ and R² are different and are independently a C₁˜C₂ alkyl group. In the example of the present invention, the metal amide derivative is Hf[N(CH₃)(C₂H₅)]₄.

Preferably, the preferred embodiment further includes (a′) purging the deposition reactor 30 using Ar gas between step (a) and step (b).

Preferably, the preferred embodiment further includes (b′) purging the deposition reactor 30 using Ar gas between step (b) and step (c).

Preferably, the preferred embodiment further includes (c′) purging the deposition reactor 30 using Ar gas between step (c) and step (d).

Preferably, the preferred embodiment further includes (d′) purging the deposition reactor 30 using Ar gas between step (d) and step (e).

Preferably, the preferred embodiment further includes (e′) purging the deposition reactor 30 using Ar gas between step (e) and step (f).

Preferably, the preferred embodiment further includes (f′) purging the deposition reactor 30 using Ar gas after step (f).

As compared to the conventional ALD process, the free radicals, such as OH. and H., employed in the method of this invention have a much smaller molecular size and a much higher activity than water vapor such that the free radicals can overcome the steric hindrance effect of the large molecules of the ligands of the chemisorption layer for reacting with the ligand groups of the chemisorption layer that are left unreacted and trapped in the metal oxide layer 22 in step (b) and step (e). In addition to the new reaction sites provided by the water vapor in step (b), the bonding of the oxygen-containing free radicals to the metal oxide layer 22 in step (c) and in step (f) of each repeated cycle provides new reaction sites for further chemisorption reaction, which facilitates crosslinking of molecules of the metal oxide layer 22 on the substrate 20, which, in turn, facilitates growth of a higher density of the metal oxide layer 22. Hence, by removing the ligand groups of the chemisorption layer that are left unreacted and trapped in the metal oxide layer in step (b) and step (e) and by providing new oxygen-containing reaction sites by virtue of the oxygen-containing free radicals, the metal oxide layer 22 thus formed can become denser, and thus can effectively prevent Si atoms of the Si substrate 20 from diffusing into the metal oxide layer 22 and prevent formation of an undesired interfacial layer during gate first process or post deposition annealing (PDA) of the MOSFET.

Preferably, the time period in step (c) or step (f) is controlled to be less than 10 seconds during the first ten cycles so as to avoid formation of a SiO₂ layer on the Si substrate, and to be greater than 10 seconds after the tenth cycle so as to generate more oxygen-containing reaction sites on the metal oxide layer 22.

Preferably, the free radical source in the plasma generator 40 has a partial pressure ranging from 0.001 Torr to 0.2 Torr. It should be noted herein that the partial pressure of the free radical source depends on the volume of the deposition reactor 30. The higher the volume of the deposition reactor 30, the higher will be the partial pressure of the free radical source.

Preferably, the plasma generator 40 is a radio-frequency plasma generator, and has a RF output power ranging from 20 W to 1000 W.

Preferably, Ar is introduced into the plasma generator 40 under a volume flow rate ranging from 50 sccm to 500 sccm in step (c) and step (f).

Preferably, the second working pressure in the deposition reactor 30 ranges from 0.1 Torr to 5 Torr.

### Example

### Pre-Treatment

Two Si substrates each having a 4 inch diameter and native oxide layers formed thereon were cleaned using a hydrofluoric acid (HF) solution, that contains 1 vol % HF and 99 vol % H₂O, for 60 minutes so as to remove the native oxide layers thereon.

### Example 1

Referring to FIGS. 1 and 2, one of the Si substrates thus cleaned was placed in a 2700 cm³ deposition reactor 30 operated at a second working pressure of 1 Torr. Hf[N(CH₃)(C₂H₅)]₄ used as a first precursor of an organometallic compound was introduced into the deposition reactor 30 under a partial pressure of 0.05 Torr for 0.5 second so as to react with oxygen-containing reaction sites (OH⁻) of the Si substrate, thereby forming a chemisorption layer of the first precursor on the Si substrate (step (a)). The deposition reactor 30 was then purged using Ar, which was introduced into the deposition reactor 30 under a volume flow rate of 200 sccm, for 3 seconds (step (a′)). Water vapor used as a second precursor was introduced into the deposition reactor 30 under a partial pressure of 0.05 Torr for 1.5 seconds so as to remove the ligand groups of the chemisorption layer that were left unreacted (step (b)), thereby forming a metal oxide layer 22. The deposition reactor 30 was purged using Ar, which was introduced into the deposition reactor 30 under a volume flow rate of 200 sccm, for 3 seconds (step (b′)). Ar and H₂O were introduced into the plasma generator 40 under a volume flow rate of 200 sccm and a partial pressure of 0.025 Torr. H₂O was ionized by 25 W of RF output power so as to form ions of OH⁻ and H⁺, and free radicals of OH. and H.. The ions and free radicals thus formed were then carried by Ar from the plasma generator 40 to pass through the metal mesh 52 into the deposition reactor 30 to thereby react with the ligand groups that were left unreacted in step (b) for 5 seconds (step (c)). The deposition reactor 30 was then purged using Ar, which was introduced into the deposition reactor 30 under a volume flow rate of 200 sccm, for 3 seconds (step (c′)). The substrate having the HfO₂ layer formed thereon was repeatedly subjected to the same reaction conditions as steps (a) to (c′) for 19 cycles so as to thicken the HfO₂ layer. The average growth rate is 0.1 nm/cycle. The HfO₂ layer thus formed after 20 cycles has a layer thickness of 2 nm.

### Comparative Example

### CE1

The other of the Si substrates thus cleaned was subjected to deposition using the conventional ALD process, i.e., without the steps (c), (c′), (f), and (f′).

### Post Deposition Annealing

### PDA

Each of the HfO₂ layers of Example 1 and Comparative Example 1 (CE1) formed on the Si substrates were cut into five specimens. The specimens were subjected to post deposition annealing (PDA) in an environment containing Ar at 500° C., 600° C., 700° C., 800° C., and 900° C. for 5 seconds to 30 seconds, respectively, followed by annealing in an environment containing H₂ (20 vol %) and Ar (80 vol %) at 300° C. for 15 minutes.

### Preparation of MOS Capacitors

Each of the annealed specimens of Example 1 and Comparative Example 1 (CE1) was deposited with a Ti layer, which serves as an upper electrode of a MOS capacitor and has a layer thickness of 300 nm and a diameter of 50 μm, on the HfO₂ layer, and a Pt layer, which serves as a lower electrode of the MOS capacitor and has a layer thickness of 100 nm, on a back surface of the Si substrate opposite to the HfO₂ layer using sputtering techniques.

### Electrical Test

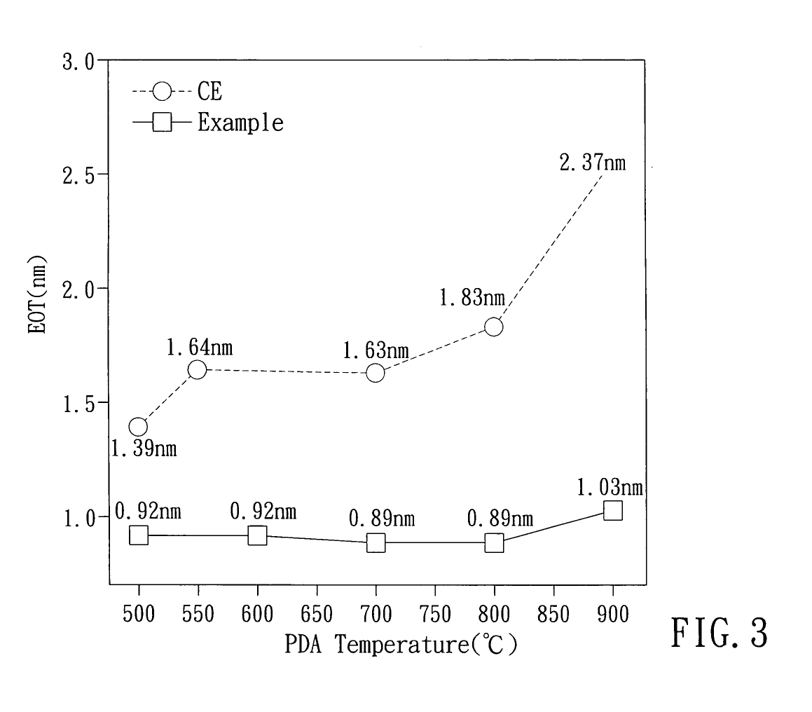

The relation between the PDA temperature and EOT of the MOS capacitor of each of Example 1 and Comparative Example 1 was obtained by calculating the I-V characteristic curves (not shown) and the C-V characteristic curves (not shown) of Example 1 and Comparative Example 1 (CE1) using a simulator. FIG. 3 shows that the EOT of Comparative Example 1 (CE1) is increased by 0.98 nm (from 1.39 nm to 2.37 nm), while the EOT of Example 1 is increased by only 0.11 nm (from 0.92 nm to 1.03 nm).

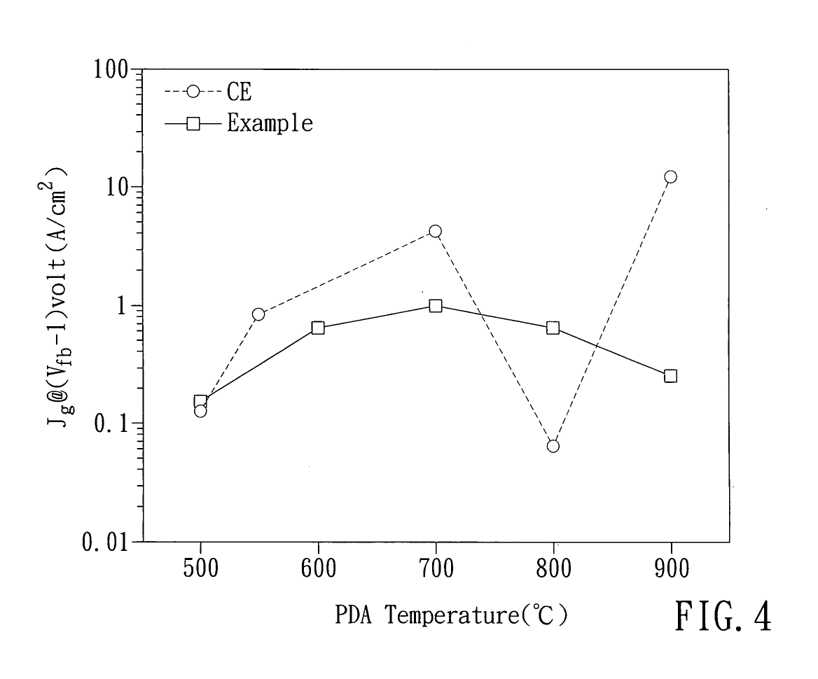

FIG. 4 shows the relation between the PDA temperature and current leakage (J_{g}) of the MOS capacitor of each of Comparative Example 1 (CE1) and Example 1 (E1). The results show that the current leakage (J_{g}) of the MOS capacitor of Comparative Example 1 is increased to 10 A/cm² after the PDA treatment with an operating temperature up to 900° C., while the current leakage (J_{g}) of the MOS capacitor of Example 1 is maintained at 0.3 A/cm² after the same PDA treatment.

In conclusion, in the method of the present invention, by exposing the metal oxide layer 22 formed in step (b) and (e) of each repeated cycle to the free radical-containing gas, most of the ligand groups can be removed from the metal oxide layer 22, thereby resulting in formation of a dense metal oxide layer on the substrate and eliminating the aforesaid drawback associated with the prior art. The MOS capacitor having the metal oxide layer 22 formed according to the method of this invention exhibits a lower EOT and a lower current leakage.

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

What is claimed is:

1. A method for making a metal oxide layer, comprising:
(a) exposing a substrate having oxygen-containing reaction sites to an environment of a first precursor of an organometallic compound, which contains a metal atom and ligand groups, so as to form a chemisorption layer of the first precursor on the substrate;
(b) exposing the chemisorption layer on the substrate to a non-free radical environment of a second precursor after step (a) so as to remove the ligand groups of the chemisorption layer that are left unreacted in step (a) and so as to convert the chemisorption layer into a metal oxide layer; and
(c) after step (b), exposing the metal oxide layer on the substrate to a free radical-containing gas containing free radicals so as to remove the ligand groups that are left unreacted and trapped in the metal oxide layer in step (b).

2. The method of claim 1, wherein exposing the metal oxide layer on the substrate to the free radical-containing gas is conducted in a deposition reactor, the free radical-containing gas being formed by using a plasma generator having a first working pressure, and being subsequently introduced into the deposition reactor from the plasma generator, the deposition reactor having a second working pressure, the first working pressure being greater than the second working pressure so as to permit discharging of the free radical-containing gas from the plasma generator into the deposition reactor.

3. The method of claim 2, wherein the plasma generator is connected to the deposition reactor through a connecting pipe, the method further comprising passing the free radical-containing gas through a metal mesh disposed in the connecting pipe during discharging of the free radical-containing gas from the plasma generator into the deposition reactor so as to permit cations and anions of the free radical-containing gas to be neutralized by the metal mesh.

4. The method of claim 2, further comprising: (d) exposing the metal oxide layer on the substrate to the environment of the first precursor for forming a chemisorption layer of the first precursor on the metal oxide layer on the substrate; (e) after step (d), exposing the chemisorption layer on the metal oxide layer on the substrate to the environment of the second precursor for removing the ligand groups of the chemisorption layer that are left unreacted in step (d) so as to thicken the metal oxide layer; (f) after step (e), exposing the thickened metal oxide layer on the substrate to the free radical-containing gas for removing the ligand groups that are left unreacted and trapped in the thickened metal oxide layer in step (e); and (g) repeating steps (d)-(f) until a predetermined layer thickness of the metal oxide layer is achieved.

5. The method of claim 4, wherein the free radical-containing gas further includes an inert gas for carrying the free radicals, the free radicals being formed by ionizing a free radical source in the plasma generator, the free radical source being H₂O, O₂, H₂O₂, O₃, N₂O, or combinations thereof.

6. The method of claim 5, wherein the second precursor is H₂O, the inert gas and the free radical source being Ar and H₂O, respectively.

7. The method of claim 6, wherein the free radical source in the plasma generator has a partial pressure ranging from 0.001 Torr to 0.2 Torr.

8. The method of claim 6, wherein the plasma generator is a radio-frequency plasma generator, and has a RF output power ranging from 20 W to 1000 W.

9. The method of claim 6, wherein Ar is introduced into the plasma generator under a volume flow rate ranging from 50 sccm to 500 sccm in step (c) and step (f).

10. The method of claim 2, wherein the second working pressure in the deposition reactor ranges from 0.1 Torr to 5 Torr.

11. The method of claim 1, wherein the organometallic compound is a metal amide derivative and has a formula of A (NR¹R²)ₙ, in which A is Hf, Ti, Al, Zr, Ta, Y, or La, R¹ and R² can be the same or different and are independently C₁˜C₂ alkyl, C₂˜C₃ alkenyl, or H, and 3≦n≦5.

12. The method of claim 11, wherein A is Hf, and R¹ and R² are independently a C₁˜C₂ alkyl group.

13. The method of claim 12, wherein the metal amide derivative is Hf[N(CH₃)(C₂H₅)]₄.

14. The method of claim 4, further comprising purging the deposition reactor using Ar gas between step (a) and step (b).

15. The method of claim 14, further comprising purging the deposition reactor using Ar gas between step (b) and step (c).

16. The method of claim 15, further comprising purging the deposition reactor using Ar gas between step (c) and step (d).

17. The method of claim 16, further comprising purging the deposition reactor using Ar gas between step (d) and step (e).

18. The method of claim 17, further comprising purging the deposition reactor using Ar gas between step (e) and step (f).

19. The method of claim 18, further comprising purging the deposition reactor using Ar gas after step (f).
